(19) United States
(12) Patent Application Publication
(10) Pub. No.: US 2026/0029490 A1
(43) Pub. Date: Jan. 29, 2026

(54) RE-MAGNETIZATION OF A MULTI-TURN SPIRAL

(71) Applicant: Analog Devices International Unlimited Company, Limerick (IE)

(72) Inventors: Jochen Schmitt, Biedenkopf (DE); Jan Kubik, Limerick (IE); Gavin Patrick Cosgrave, Enniscorthy (IE)

(21) Appl. No.: 18/787,674

(22) Filed: Jul. 29, 2024

(51) Int. Cl. G01R 33/00; G01R 33/02; G01R 33/09; H01F 13/00

(52) U.S. Cl. CPC G01R 33/0005; G01R 33/0206; G01R 33/093; H01F 13/00

(57) ABSTRACT

Aspects of this disclosure relate to systems and methods for re-magnetization of a multi-turn loop. In one aspect, a multi-turn magnetic sensing system includes a multi-turn loop through which domain walls propagate in response to rotation of a magnetic field and a magnetization component configured to provide domain walls to the multi-turn loop. The system further includes one or more wires configured to annihilate at least two of the domain walls of the multi-turn loop.

### BACKGROUND

### Technical Field

The disclosed technology relates to multi-turn magnetic sensors and related systems and methods.

### Description of Related Technology

A magnetic sensing system can include a multi-turn magnetic sensor that counts a cumulative number of rotations of a magnetic field. A multi-turn magnetic sensor can include magnetoresistive elements that are arranged in series with each other as a spiral shaped strip. Resistance of one or more of the magnetoresistive elements can change in response to rotation of a magnetic field. The state of the multi-turn magnetic sensor can be decoded from output signals of the multi-turn magnetic sensor.

### SUMMARY OF CERTAIN INVENTIVE ASPECTS

The innovations described in the claims each have several aspects, no single one of which is solely responsible for its desirable attributes. Without limiting the scope of the claims, some prominent features of this disclosure will now be briefly described.

One aspect of this disclosure is a multi-turn magnetic sensing system comprising: a multi-turn loop through which domain walls propagate in response to rotation of a magnetic field; a magnetization component configured to provide the domain walls to the multi-turn loop; and one or more wires configured to annihilate at least two of the domain walls of the multi-turn loop.

In some embodiments, the magnetization component comprises a reset coil wire configured to fill the multi-turn loop with domain walls.

In some embodiments, the multi-turn magnetic sensing system further comprises a decoder configured to output a turn count that is based on output signals from the multi-turn loop, wherein the decoder is configured to determine the turn count in based on a location of a domain wall gap formed by the annihilation of the at least two of the domain walls.

In some embodiments, the one or more wires comprise a re-magnetization coil that wraps around a portion of the multi-turn loop.

In some embodiments, the one or more wires comprise a re-magnetization component positioned on one side of a portion of the multi-turn loop.

In some embodiments, the multi-turn loop comprises a multi-turn spiral, and wherein the one or more wires comprise a re-magnetization component that covers at least three quarters of a turn of the multi-turn spiral.

In some embodiments, the multi-turn magnetic sensing system further comprises a read out circuit configured to measure a direction of an external magnetic field; and a controller configured to apply a current pulse to the one or more wires with a direction of the current pulse based on the measured external magnetic field.

In some embodiments, the read out circuit is further configured to measure a magnetization state of the multi-turn loop, and the controller is configured to verify that the at least two of the domain walls were annihilated based on the measured magnetization state of the multi-turn loop.

In some embodiments, the multi-turn loop comprises a multi-turn spiral, and wherein the magnetization component comprises: a domain wall generator configured to generate domain walls at one end of the multi-turn spiral; and a magnetic target configured to generate an external magnetic field, wherein the providing domain walls to the multi-turn spiral comprises turning the magnetic target with respect to the multi-turn spiral such that the domain walls generated by the domain wall generator propagate around the multi-turn spiral.

In some embodiments, the magnetization component comprises: one or more reset coils wires configured to generate a magnetic field having a strength sufficient to fill the multi-turn loop with the domain walls.

In some embodiments, the multi-turn loop comprises a multi-turn spiral including a first spiral and a second spiral, the first spiral and the second spiral coupled together such that domain walls can propagate between the first and second spirals.

In some embodiments, the one or more wires comprise a re magnetization component including a plurality of sections, and the multi-turn magnetic sensing system further comprises a controller configured to apply current pulses to the sections of the re-magnetization component in sequence.

Another aspect of this disclosure is a method of initializing a multi-turn magnetic sensing system, the method comprising: providing domain walls to a multi-turn loop; and applying a magnetic field to a portion of the multi-turn loop to annihilate at least two of the domain walls of the multi-turn loop, wherein after the applying the multi-turn loop is configured to change state in response to rotation of a magnetic field.

In some embodiments, the method further comprises determining a turn count based on output signals from the multi-turn loop.

In some embodiments, the determining is based on a location of a domain wall gap formed by the annihilation of the at least two of the domain walls.

In some embodiments, the applying is performed using a coil that wraps around a portion of the multi-turn loop.

In some embodiments, the method further comprises measuring a direction of an external magnetic field, wherein the applying comprises applying a current pulse to a re-magnetization component, and wherein a direction of the current pulse is based on the measured external magnetic field.

In some embodiments, the method further comprises measuring a magnetization state of the multi-turn loop; and verifying that the at least two of the domain walls were annihilated based on the measured magnetization state of the multi-turn loop.

In some embodiments, the providing the domain walls to the multi-turn loop is performed using one or more reset coils wires that generate a magnetic field having a strength sufficient to fill the multi-turn loop with the domain walls.

Yet another aspect of this disclosure is a multi-turn magnetic sensing system comprising: a multi-turn loop through which domain walls propagate in response to rotation of a magnetic field; means for annihilating at least two of the domain walls of the multi-turn loop; and a decoder configured to output a turn count that is based on output signals from the multi-turn loop.

### BRIEF DESCRIPTION OF THE DRAWINGS

Embodiments of this disclosure will be described, by way of non-limiting example, with reference to the accompanying drawings.

FIG. 1 illustrates a multi-turn spiral in accordance with aspects of this disclosure.

FIG. 2 is a schematic block diagram of a multi-turn magnetic sensing system according to an embodiment.

FIG. 3 illustrates one stage in the initialization process for a multi-turn spiral in accordance with aspects of this disclosure.

FIG. 4 illustrates an example pair of domain walls in the multi-turn spiral that can be annihilated in accordance with aspects of this disclosure.

FIG. 5 illustrates an embodiment of the multi-turn spiral including one or more wires configured to annihilate at least two domain walls of the multi-turn spiral in accordance with aspects of this disclosure.

FIG. 6 illustrates a portion of the re-magnetization coil with the layers partially transparent to show the connections between layers.

FIG. 7 illustrates a direction of a current flowing through the re-magnetization coil when applied with a current pulse in accordance with aspects of this disclosure.

FIG. 8 illustrates the magnetization of the multi-turn spiral after the re-magnetization of FIG. 7 in accordance with aspects of this disclosure.

FIG. 9 illustrates an example cross-section of the multi-turn spiral in accordance with aspects of this disclosure.

FIG. 10 illustrates another embodiment of the multi-turn spiral including a re-magnetization component which can be used to re-magnetize a portion of the multi-turn spiral in accordance with aspects of this disclosure.

FIG. 11 shows an example method for initializing a multi-turn spiral in accordance with aspects of this disclosure.

FIG. 12 shows another example method for initializing a multi-turn spiral in accordance with aspects of this disclosure.

FIG. 13 illustrates another embodiment of the multi-turn spiral including a magnetization component which can be used to fill the multi-turn spiral with domain walls in accordance with aspects of this disclosure.

FIG. 14 illustrates another embodiment of a multi-turn spiral in accordance with aspects of this disclosure.

FIG. 15A illustrates an embodiment of a multi-turn counter loop in accordance with aspects of this disclosure.

FIG. 15B illustrates another embodiment of a multi-turn counter loop in accordance with aspects of this disclosure.

FIG. 15C illustrates yet another embodiment of a multi-turn counter loop in accordance with aspects of this disclosure.

FIG. 16 illustrates still yet another embodiment of a multi-turn spiral in accordance with aspects of this disclosure.

FIG. 17 illustrates another embodiment of a multi-turn spiral in accordance with aspects of this disclosure.

FIG. 18 illustrates another embodiment of the multi-turn spiral including one or more wires configured to annihilate at least two domain walls of the multi-turn spiral in accordance with aspects of this disclosure.

FIG. 19 illustrates yet another embodiment of the multi-turn spiral including a re-magnetization component which can be used to re-magnetize a portion of the multi-turn spiral in accordance with aspects of this disclosure.

FIG. 20 illustrates still yet another embodiment of the multi-turn spiral including a re-magnetization component which can be used to re-magnetize a portion of the multi-turn spiral in accordance with aspects of this disclosure.

FIG. 21 shows an example method for initializing a multi-turn magnetic sensing system in accordance with aspects of this disclosure.

FIG. 22A is a schematic diagram of two multi-turn sensors of a multi-turn magnetic sensing system according to an embodiment.

FIG. 22B is a table summarizing state and turn count for the multi-turn magnetic sensing system of FIG. 22A as a magnetic field rotates.

### DETAILED DESCRIPTION

The following detailed description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the illustrated elements. Further, some embodiments can incorporate any suitable combination of features from two or more drawings. The headings are provided for convenience only and do not impact the scope or meaning of the claims.

### Multi-turn Magnetic Sensors

Multi-turn magnetic sensors can continuously detect rotary or linear motion in the absence of electric power and absolute position can be read back on power-on. Multi-turn magnetic sensors can provide true power-on capabilities without receiving power. Multi-turn magnetic sensors can operate on the principle of a magnetic spiral or track detecting motion in the presence of a moving permanent magnet. The magnetic spiral can include nanowires. The magnetic spiral can comprise giant magnetoresistive (GMR) material or tunnel magnetoresistive (TMR) material. The resistance of magnetoresisitve elements of the magnetic spiral can change as the magnetic spiral fills with domain walls, which can also be referred to as magnetic domains, in response to rotation of a magnetic field. This effect can be referred to as form anisotropy. A turn count can be decoded from resistances of magnetoresistive elements of the multi-turn magnetic sensor. The turn count can be combined with an angle detected by an angle sensor to provide absolute multi-turn position information.

A technical challenge with multi-turn magnetic sensors is initializing and/or resetting the multi-turn magnetic sensor at a mid-position or another specific position of the measurement range. Setting the multi-turn magnetic sensor to such a position can correspond to a turn count that is between ends of a turn count range. This can be desirable, for example, for when the magnetic target is configured to be turned in either direction from its initial position. This disclosure provides technical solutions to this challenge.

Embodiments of this disclosure can initialize or otherwise set a multi-turn magnetic sensor to a particular state. Magnetic turn count information stored in the multi-turn magnetic should correspond to a physical turn count of a system that includes the multi-turn magnetic sensor. Setting the multi-turn sensor turn count state to a mid-point or another specific point can be desirable. Certain initialization techniques set multi-turn magnetic sensors to an end point of a turn count range. For instance, the multi-turn magnetic sensor can be initialized to a state where the multi-turn magnetic sensor is completely filled with domain walls. This disclosure provides technical solutions to magnetically set the multi-turn magnetic sensor to a different state.

Aspects of this disclosure relate to systems and techniques for re-magnetizing a portion of multi-turn loop, such as a multi-turn spiral. This can be used to set the multi-turn sensor magnetization to a specific turn count state, for example, other than a minimum value of a turn count range or a maximum value of the turn count range.

### Resetting Multi-Turn Magnetic Sensors

A multi-turn magnetic sensor can be reset by applying a magnetic field having a magnitude that is higher than an upper operating magnetic limit of the multi-turn magnetic sensor. This can result in a magnetic spiral of a multi-turn magnetic sensor filling with domain walls. In some cases, such a reset can correspond to the multi-turn magnetic sensor being in a maximum turn count state. In some other applications, resetting a magnetic spiral of a multi-turn magnetic sensor can result in the multi-turn magnetic sensor being in a minimum turn count state with a magnetic spiral that is empty of domain walls.

The magnetic spiral can take the form of a clockwise (CW) sensor or a counterclockwise (CCW) sensor. A CW multi-turn magnetic sensor can count turns in the presence of a magnetic field rotating in CW direction. In such a multi-turn magnetic sensor, the turn count can correspond to magnetoresistive elements of a magnetic spiral being filled with domain walls. The magnetoresistive elements can be legs of the magnetic spiral. A CCW multi-turn magnetic sensor can count turns in the presence of a magnetic field rotating in CCW direction. Domain walls propagate in an opposite direction in a CW multi-turn magnetic sensor relative to a CCW multi-turn magnetic sensor.

### Example Multi-Turn Spiral

Aspects of this disclosure relate to systems and techniques for re-magnetizing a portion of multi-turn spiral. This can be used to set the multi-turn sensor magnetization to a specific turn count state, for example, other than a minimum value of a turn count range and a maximum value of the turn count range.

As described herein, certain multi-turn sensors do not have the ability to reset the multi-turn sensors at a mid-point between minimum and maximum values of a turn count range. For various applications, it is desirable to reset and/or initialize multi-turn sensors to a specific turn count state between the minimum and maximum values of the turn count range.

Accordingly, aspects of this disclosure provide systems and techniques for the initialization of multi-turn sensors that enables new implementations of the multi-turn technology. In order to accurately measure the turn count, the magnetic turn count information stored in the sensor should match with the physical turn count of the system the sensor is measuring. In many applications, the physical system being measured may be configured to turn in either direction (e.g., CW or CCW). Thus, it is desirable to set the multi-turn sensor turn count state to a mid-point or another specific point, enabling measurement in either direction from the set state.

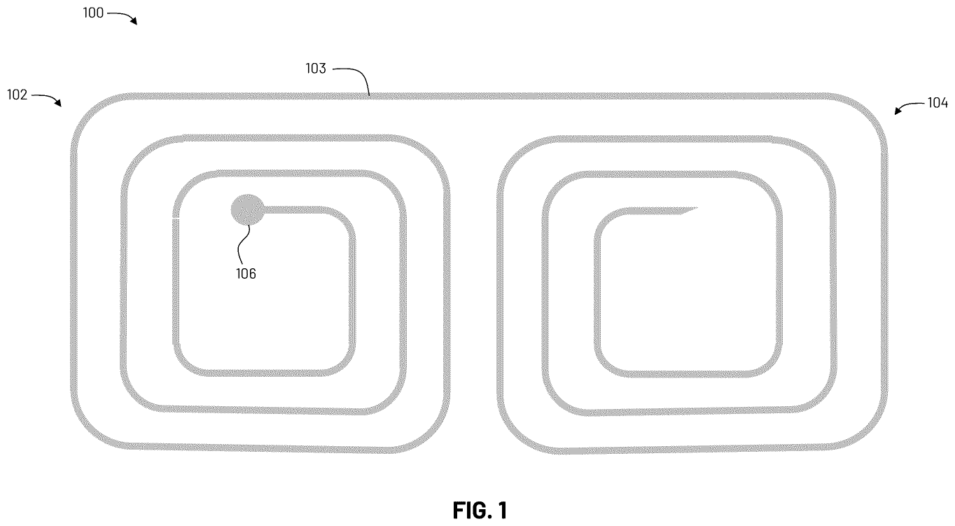

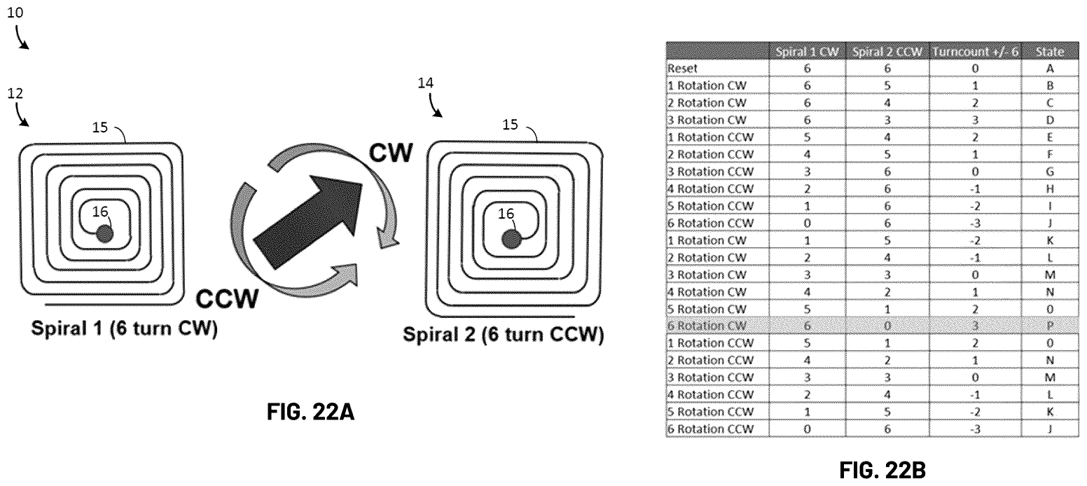

FIG. 1 illustrates a multi-turn spiral 100 in accordance with aspects of this disclosure. The multi-turn spiral 100 is an example of a multi-turn loop. As shown in FIG. 1, the multi-turn spiral 100 includes a first spiral 102 and a second spiral 104 coupled together such that domain walls can propagate between the first and second spirals 102 and 104. The first spiral 102 and second spiral 104 can be include a plurality of spiral arms, where each spiral arm is formed from a single winding of the spiral 102, 104. The first spiral 102 and second spiral 104 can be formed from a nanowire 103. The multi-turn spiral 100 also includes a domain wall generator 106 at an end of the multi-turn spiral 100. Although embodiments of this disclosure are described in connection with the multi-turn spiral 100 illustrated in FIG. 1, aspects of this disclosure are not limited thereto and the re-magnetization systems and techniques can also be applied to various other types of multi-turn sensors including, for example, the multi-turn magnetic sensing system 10 of FIG. 22A, and/or single spiral multi-turn sensors.

Multi-Turn Magnetic Sensing Systems with Mid-Position Reset

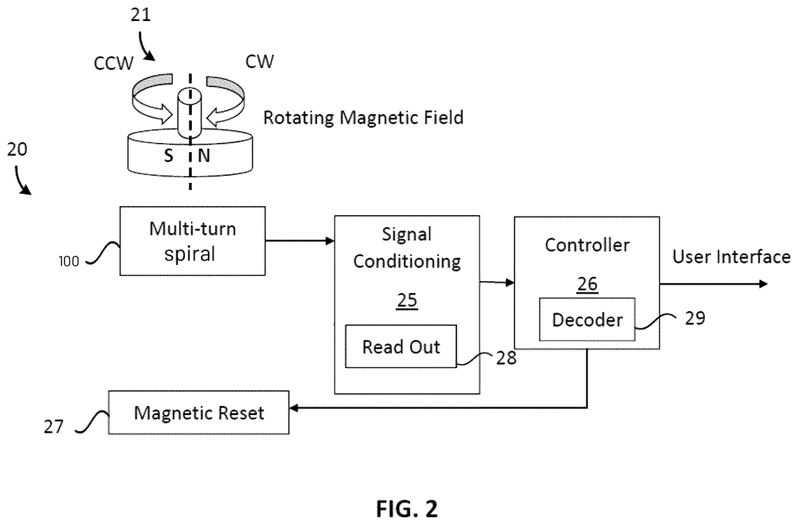

Mid-position reset can be implemented in various multi-turn magnetic sensing systems. Such multi-turn magnetic sensing systems can include processing circuitry and a magnetic reset. The processing circuitry can include a signal conditioning circuit and a controller. In certain applications, multi-turn magnetic systems can include one or more additional sensors, such as an angle sensor and/or a quadrant detector. Example multi-turn magnetic sensing systems with mid-position reset will be discussed with reference to FIG. 2.

FIG. 2 is a schematic block diagram of a multi-turn magnetic sensing system 20 according to an embodiment. The multi-turn magnetic sensing system 20 can track and output a turn count representing a number of turns of an operation magnetic field that can be generated by rotation of a magnetic target 21 or other magnetic field source. As illustrated, the magnetic target 21 can be a dipole magnet. The magnetic target 21 can be mounted to a rotating shaft in certain applications. The multi-turn magnetic sensing system 20 includes a multi-turn spiral 100, a signal conditioning circuit 25, a controller 26, and a magnetic reset 27. In some embodiments, the multi-turn spiral 100 can be embodied as the multi-turn spiral 100 of FIG. 1 or any other multi-turn spiral described herein. Example magnetic spirals are shown in FIGS. 1 and 22A.

The multi-turn spiral 100 can be configured to track any suitable number of turns for a particular application.

Output signals from the multi-turn spiral 100 are conditioned by the signal conditioning circuit 25. The signal conditioning circuit 25 can include any suitable circuitry to modify raw analog output signals from the multi-turn spiral 100 to make the signals suitable for further processing. The signal conditioning circuit 25 can include one or more amplifiers and/or one or more filters, for example. The signal conditioning circuit 25 can include a read out circuit 28 that reads out values associated with magnetoresistive elements of the multi-turn spiral 100. In certain applications, the read out circuit 28 can be implemented in accordance with any suitable principles and advantages disclosed in U.S. Pat. No. 10,782,153, the disclosure of which is hereby incorporated by reference in its entirety and for all purposes. A signal generated by the read out circuit 28 can be indicative of resistance of one or more of magnetoresistive elements of the first multi-turn magnetic sensor 22 or the second multi-turn magnetic sensor 24.

The controller 26 can include a decoder 29 that can determine a cumulative turn count of the operation magnetic field from output signals from the signal conditioning circuit 25. The controller 26 can digitize an output signal from the signal conditioning circuit 25 with an analog-to-digital converter (ADC). A digital output signal from the ADC can be provided to the decoder 29 for determining the turn count. The controller 26 can output the turn count to a user interface, for example. The user interface can be any suitable interface, including but not limited to an inter-integrated circuit (I2C) interface or a serial peripheral interface (SPI). The controller 26 can generate a control signal to control the magnetic reset 27. Depending on the embodiment, the controller 26 can include a state machine, a microcontroller, or any other similar controller.

The decoder 29 can output a turn count that represents a cumulative number of turns of the operation magnetic field. The decoder 29 can determine any suitable values from Table 1B, for example. For instance, the decoder 29 can determine a state of the multi-turn spiral 100 and turn count. The decoder 29 can determine a state of the multi-turn spiral 100 based on the output signals from the read out circuit 28. The state of the of the multi-turn spiral 100 can be determined based on signals representing resistances of magnetoresistive elements of the multi-turn spiral 100. The decoder 29 can receive digital input signals and provide the turn count as a digital output signal. In certain applications, the decoder 29 can implement successive approximation decoding to determine the state of the multi-turn spiral 100. Such decoding can be implemented in accordance with any suitable principles and advantages disclosed in U.S. Pat. No. 10,830,613, the disclosure of which is hereby incorporated by reference in its entirety and for all purposes.

The decoder 29 can determine the turn count from the states of the multi-turn spiral 100. An example mapping of turn count to sensor states is provided in FIG. 22B. In decoding output signals from the read out circuit 28, the decoder 29 can decode valid pre-equilibrium states and valid equilibrium states. The decoder 29 can be a full turn decoder, a half turn decoder, or a quarter turn decoder.

The controller 26 can control the magnetic reset 27 to reset the multi-turn magnetic sensors 22, 24 to a reset state. Such a magnetic reset can be performed upon system initialization. In such instances, the reset state can be an initialization state. In some applications, magnetic reset can be performed in response to one or more of detecting a system fault, for rollover counting which is discussed in more detail below, periodically, after reaching a threshold amount of time for system operation, or in response to detecting any other suitable condition.

The magnetic reset 27 can include any suitable structure to reset the multi-turn spiral 100. In certain applications, the magnetic reset 27 can include a wire or a coil that can generate a reset magnetic field that is greater than an upper operating limit of the multi-turn spiral 100. The controller 26 can cause current to flow through the wire or coil to generate the reset magnetic field. The wire or coil can fill the multi-turn spiral 100 with domain walls to bring the multi-turn spiral 100 to the reset state. The wire or coil can be implemented on a printed circuit board. In some other applications, the magnetic reset 27 can include a permanent magnet that is brought into physical proximity to the multi-turn spiral 100 to apply a magnetic field that is greater than an upper operating limit of the multi-turn spiral 100. For such a permanent magnet, the controller 26 can provide a control signal to cause the permanent magnet to move sufficiently close to the multi-turn spiral 100 to bring the multi-turn spiral 100 to the reset state. Then the controller 26 can cause the permanent magnet to move away from the multi-turn spiral 100 to allow the multi-turn magnetic sensing system 20 to track rotation of a magnetic field.

### Re-Magnetization of a Portion of a Multi-Turn Spiral

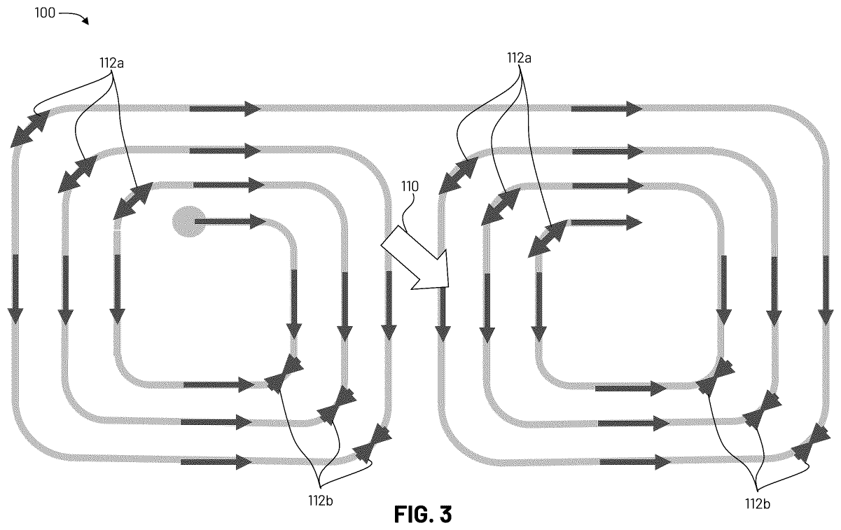

FIG. 3 illustrates one stage in the initialization process for a multi-turn spiral 2300 in accordance with aspects of this disclosure. With reference to FIG. 3, the multi-turn sensor system can apply a magnetic field 110 in order to fill the multi-turn spiral 100 with domain walls 112. In some embodiments, the magnetic field 110 may be applied by a magnetization component (e.g., the magnetic reset 27 of FIG. 2). In some embodiments, the magnetization component can comprise a domain wall generator (e.g., the domain wall generator 106 of FIG. 1) configured to provide domain walls to the multi-turn spiral 100 which can then partially or completely fill the multi-turn spiral 100 as the multi-turn spiral 100 turns with respect to the magnetic target 21. The domain walls 112 can include tail-to-tail domain walls 112a and head-to-head domain walls 112b. The remaining arrows that point in one direction illustrate the direction of the magnetization of the multi-turn spiral 100 between the domain walls 112. After being reset with the magnetic field 110, the multi-turn spiral 100 is filled with domain walls 112 as shown in FIG. 3.

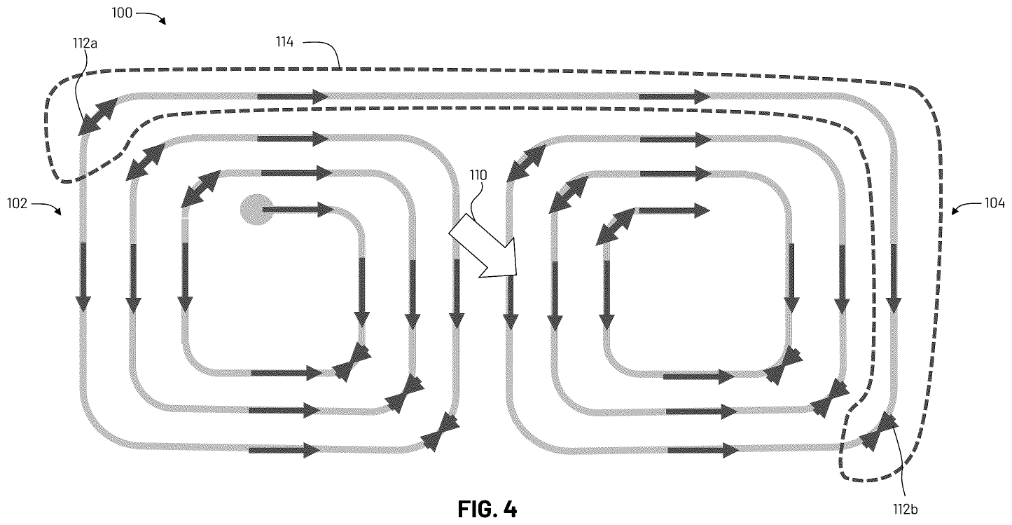

In order to initialize the multi-turn spiral 100 to a turn count between minimum and maximum values of the turn count, the multi-turn sensor can annihilate at least one pair of domain walls 112 of the multi-turn spiral 100. FIG. 4 illustrates an example pair of domain walls 112a, 112b in the multi-turn spiral 100 that can be annihilated in accordance with aspects of this disclosure. As shown in FIG. 4, the multi-turn sensor system can magnetize a portion 114 of the multi-turn spiral 100 to annihilate a pair of domain walls 112. In some embodiments, a magnetic field can be applied in the opposite direction as the magnetization of the multi-turn spiral 100 causing the pair of domain walls to propagate in opposite directions to annihilate each other. The pair of domain walls can include a tail-to-tail domain wall 112a and a head-to-head domain wall 112b. In the embodiment of FIG. 4, the portion 114 extends from the top left corner of the multi-turn spiral 100 (top left corner of the first spiral 102) to the bottom right corner of the multi-turn spiral 100 (bottom right corner of the second spiral 104).

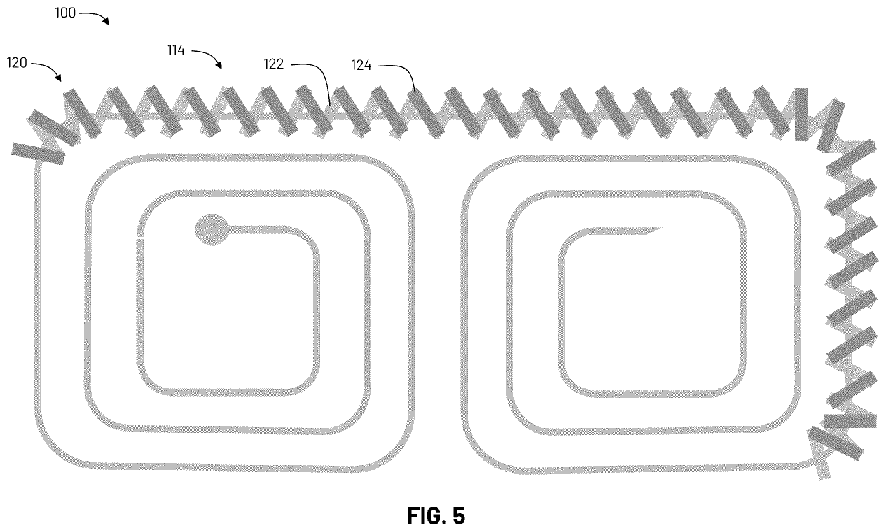

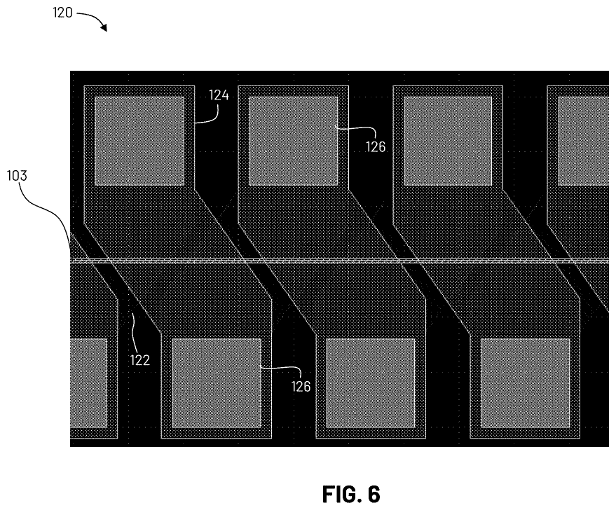

FIG. 5 illustrates an embodiment of the multi-turn spiral 100 including one or more wires configured to annihilate at least two domain walls of the multi-turn spiral 100 in accordance with aspects of this disclosure. The one or more wires can include a re-magnetization component including a re-magnetization coil 120 that can be wrapped around the portion 114 of the multi-turn spiral 100 shown in FIG. 4. The re-magnetization coil 120 can be a flat solenoidal coil wrapped around a nanowire. The re-magnetization coil 120 can include first wires 122 located below the multi-turn spiral 100 and second wires 124 located above the multi-turn spiral 100. In some embodiments, the first wires 122 and the second wires 124 can be electrically connected to each other by vias 126 (see FIG. 6). Thus, the re-magnetization coil 120 can wrap around the nanowire 103 by forming a spiral around the nanowire 103. Accordingly, the re-magnetization coil 120 can include wires 122 and 124 positioned on opposing sides of the multi-turn spiral 100 that are electrically connected to each other. The multi-turn sensor can be configured to apply a current pulse to the re-magnetization coil 120 to re-magnetize the portion 114 of the multi-turn spiral 100. For example, a controller (e.g., the controller 26 of FIG. 2) can be configured to apply the current pulse to the re-magnetization coil 120.

FIG. 6 illustrates a portion of the re-magnetization coil 120 with the layers partially transparent to show the connections between layers. In particular, FIG. 6 illustrates the vias 126 that connect the first wires 122 to the second wires 124 of the re-magnetization coil 120. A portion of the nanowire 103 forming the multi-turn spiral 100 is also shown between the first wires 122 and second wires 124 of the re-magnetization coil 120.

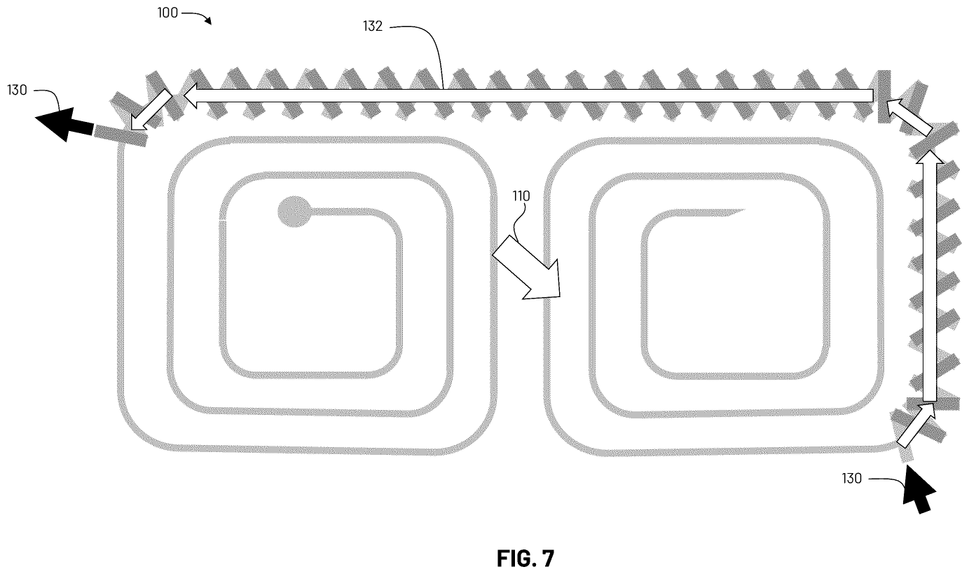

FIG. 7 illustrates a direction of a current flowing through the re-magnetization coil 120 when applied with a current pulse 130 in accordance with aspects of this disclosure. In some embodiments, it can be important to apply the current pulse to the re-magnetization coil 120 for a relatively short period of time. For example, the current pulse may be applied for a length of time on the order of a single microsecond. With reference to FIG. 7, in the illustrated embodiment the current pulse 130 is applied between the ends of the re-magnetization coil 120 and generates a magnetic field 132 along the portion 114 of the multi-turn spiral 100 overlapping the re-magnetization coil 120. In comparison to the magnetization of the portion 114 of the multi-turn spiral 100 shown by arrows in FIGS. 1 and 3, the magnetic field 132 generated by the current pulse 130 is oriented in the opposite direction. When the magnetic field 132 has a sufficient magnitude (e.g., is greater than a threshold magnetic field), the magnetic field 132 causes the portion 114 of the multi-turn spiral 100 to be re-magnetized.

FIG. 7 also illustrates the direction of the magnetic field 110 that was applied during the stage of the initialization process illustrated in FIG. 3. As shown in FIG. 7, the direction of the magnetic field 132 is substantially opposite to the direction of the magnetic field 110 so that the pair of domain walls 112 (see the tail-to-tail domain walls 112a and the head-to-head domain walls 112b of FIG. 4).

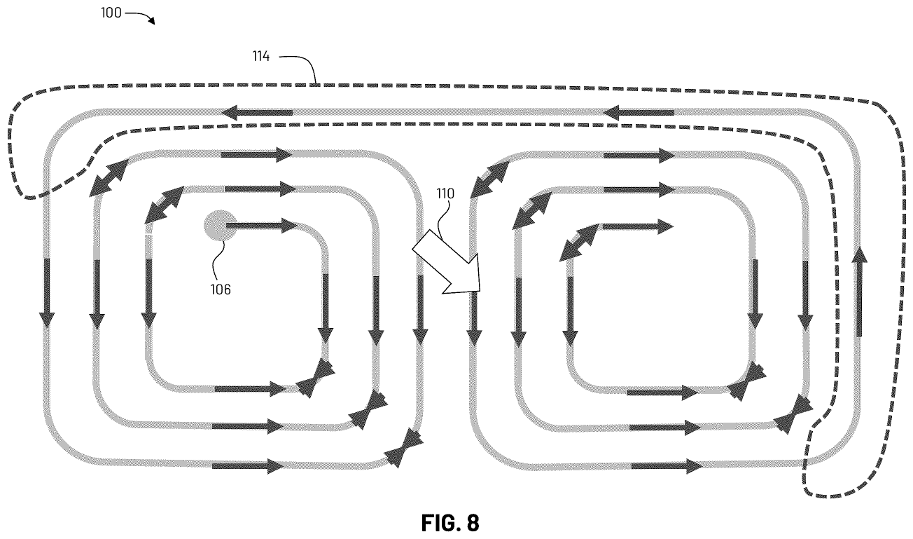

FIG. 8 illustrates the magnetization of the multi-turn spiral 100 after the re-magnetization of FIG. 7 in accordance with aspects of this disclosure. The domain walls 112 that were previously present in the portion 114 of the multi-turn spiral 100 are removed (e.g., via annihilation) and the magnetization/domain is rotated by 180 degrees. This domain wall gap in the domain walls shown in FIG. 8 compared to the configuration of FIG. 3 can be used to initialize the multi-turn spiral 100 in a mid-position (e.g., a position between minimum and maximum values of the turn count). The multi-turn sensor can determine the location of the first missing domain wall pair along the multi-turn spiral 100 starting from the domain wall generator 106, for example, by measuring the resistance of the nanowire (whether the nanowire is implemented using GMR, tunneling magnetoresistance (TMR), or another technology). The multi-turn sensor can then determine the turn count based on the determined location of the first missing domain wall pair.

Although certain embodiments are discussed with reference to initialization, any suitable principles and advantages disclosed herein can be applied to setting the state of a multi-turn spiral at one or more other times. For example, any suitable principles and advantages disclosed herein can be applied to a power down situation. As another example, any suitable principles and advantages disclosed herein can be applied to rollover counting. Rollover counting can enable a multi-turn sensor system to count turns beyond a number of turns of the multi-turn spiral. In rollover counting, the multi-turn spiral can be set to a particular state (e.g. mid stage) after reaching a particular turn count (e.g., a maximum or minimum turn count), the turn count index be stored and/or updated, and a readout circuit can determine a turn count based on the stored turn count index and a state of the multi-turn spiral.

Although FIGS. 5 and 8 illustrate an embodiment in which the re-magnetization coil 120 extends along the portion 114 of the multi-turn spiral 100, the re-magnetization coil 120 can be located along any other suitable portions of the multi-turn spiral 100 without departing from aspects of this disclosure. Thus, the multi-turn spiral 100 can be reset at different points along the multi-turn spiral 100 depending on the location of the re-magnetization coil 120. In further embodiments, a plurality of coils 120 can be included at different locations along the multi-turn spiral 100, enabling the multi-turn sensor to initialize the multi-turn spiral 100 to a plurality of different turn count states.

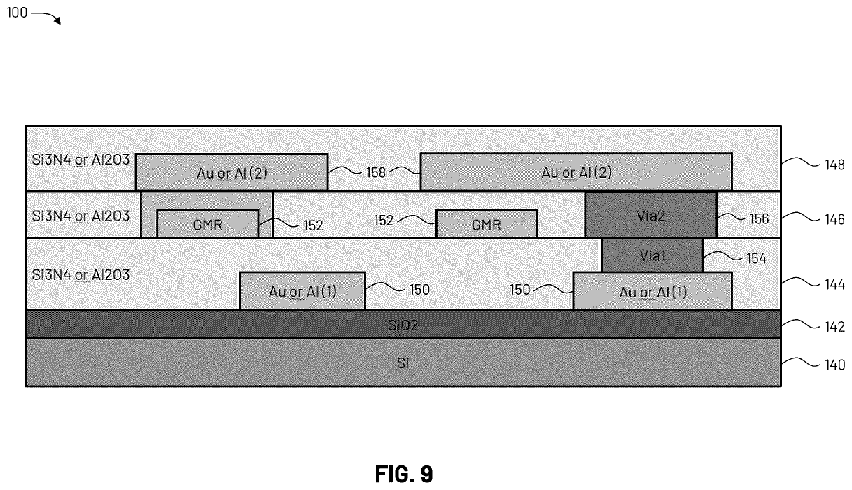

FIG. 9 illustrates an example cross-section of the multi-turn spiral 100 in accordance with aspects of this disclosure. As shown in FIG. 9, the multi-turn spiral 100 includes a silicon wafer 140 having a silicon oxide SiO₂ surface 142, a first isolation layer 144, a second isolation layer 146, a third isolation layer 148, a first metal layer 150, a nanowire layer 152, a first via layer 154, a second via layer 156, and a second metal layer 158. In some embodiments, the first metal layer 150 and the second metal layer 158 may be formed of Al, Au, Cu, alloys thereof, or any other suitable metal used for semiconductor wires. The first, second, and third isolation layers 144, 146, and 148 may be formed of Al₂O₃, Si₃N₄ or similar electrically isolating materials. The third isolation layer 148 can be a final passivation layer. The first and second via layers 154 and 156 can electrically connect the first and second metal layers 150 and 158. The re-magnetization coil 120 can be formed by the first and second metal layers 150 and 158 and electrical connections provided by the first and second vias layers 154 and 156. The nanowire layer 152 may be formed of GMR and/or TMR material.

Those skilled in the art will appreciate that the arrangement illustrated in FIG. 9 is merely one embodiment of the multi-turn spiral 100 and the multi-turn spiral 100 can be implemented in various different ways.

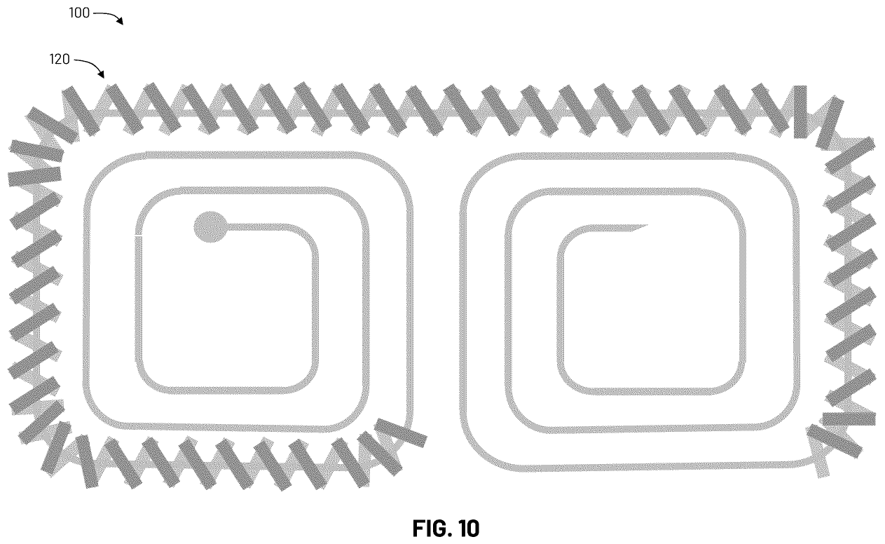

FIG. 10 illustrates another embodiment of the multi-turn spiral 100 including a re-magnetization component which can be used to re-magnetize a portion of the multi-turn spiral 100 in accordance with aspects of this disclosure. In contrast to the embodiment of FIG. 5, the re-magnetization component of the embodiment in FIG. 10 includes a re-magnetization coil 120 that covers a larger portion of the multi-turn spiral 100. For example, the re-magnetization coil 120 can cover a full turn of the multi-turn spiral 100. FIG. 10 illustrates an example re-magnetization coil 120 that covers a full turn of the multi-turn spiral 100.

When the multi-turn spiral 100 is filled with domain walls 112, the locations of the domain walls may vary, for example, due to the magnetic field 110. With reference back to FIG. 3, the multi-turn spiral 100 can be filled with domain walls 112 with the domain walls 112 located in the top left and bottom right corners of the multi-turn spiral 100. However, if the magnetic field 110 is rotated by about 90 degrees in either direction, the domain walls 112 should be located in the bottom left and top right corners of the multi-turn spiral 100. In this case, the re-magnetization coil 120 of FIG. 5 would only cover a single domain wall, and thus, may not be able to annihilate a pair of domain walls.

In contrast, the multi-turn spiral 100 of FIG. 10 includes the re-magnetization coil 120 that covers a full turn of the multi-turn spiral 100. Accordingly, the re-magnetization coil 120 will cover at least two domain walls 112 regardless of the orientation of the external magnetic field 110. Thus, the multi-turn spiral 100 can more robustly annihilate a pair of domain walls 112 within the area covered by the re-magnetization coil 120. The multi-turn sensor may also be configured to apply the current pulse to the re-magnetization coil 120 in either direction to ensure that the domain walls 112 located within the re-magnetization coil 120 can be annihilated. A re-magnetization coil 120 that covers three quarters of a turn of the multi-turn magnetic sensor can be sufficient to annihilate a domain wall pair under any operation magnetic field.

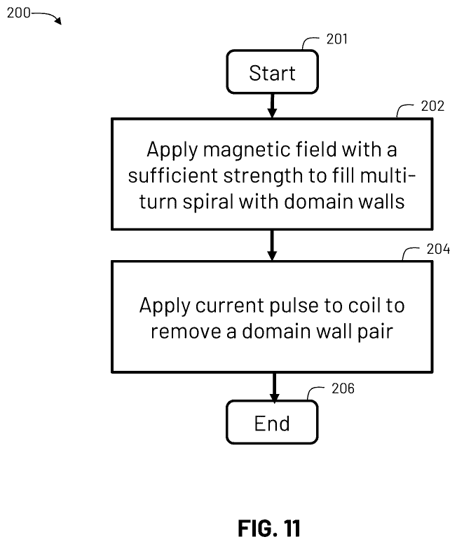

FIG. 11 shows an example method 200 for initializing a multi-turn spiral 100 in accordance with aspects of this disclosure. The method 200 begins at block 201.

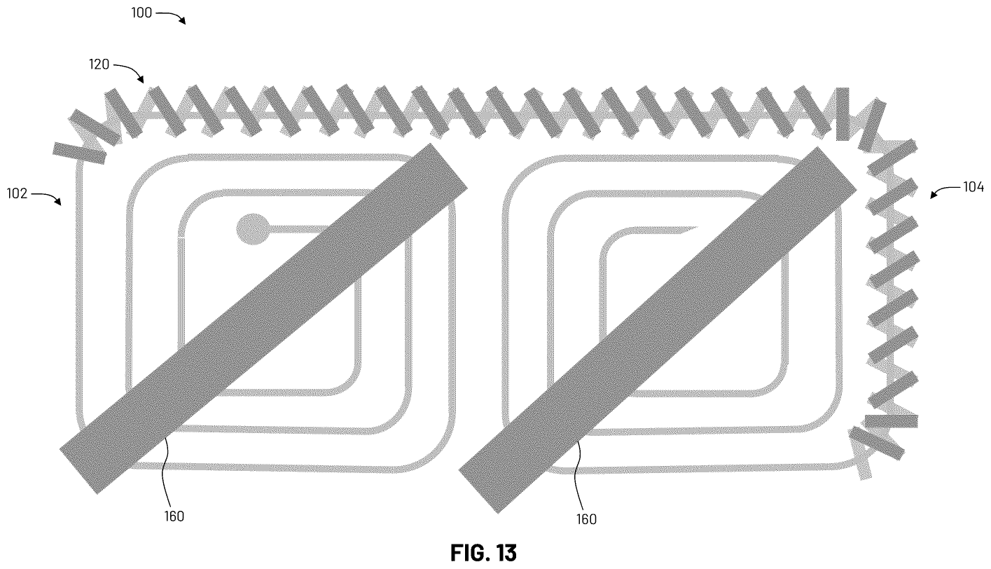

At block 202, a multi-turn sensor system applies a magnetic field to the multi-turn spiral 100 having a sufficient strength to fill the multi-turn spiral 100 with domain walls. In some embodiments, the multi-turn sensor system can apply the magnetic field using a reset coil (such as the magnetic reset 27 of FIG. 2) or a reset wire (such as the reset wires 160 of FIG. 13). The multi-turn sensor system applies a magnetic field to the multi-turn spiral 100 under the presence of an operation magnetic field which may be generated by a magnet such as the magnetic target 21 of FIG. 2. In some cases, the operation magnetic field may have an arbitrary direction, and thus, the strength of the magnetic field applied to the multi-turn spiral 100 may be above a threshold that can fill the multi-turn spiral 100 with domain walls regardless of the direction of the operation magnetic field.

At block 204, the multi-turn sensor system applies a current pulse to the re-magnetization coil 120 to remove at least one pair of domain walls in the multi-turn spiral 100. The method 200 ends at block 206. At this point, the multi-turn spiral 100 is set to a state that corresponds to a turn count that is between ends of a turn count range. Accordingly, the multi-turn spiral 100 can change state in response to rotation of a magnetic field in either a CW direction or CCW direction from the state set by the method 200.

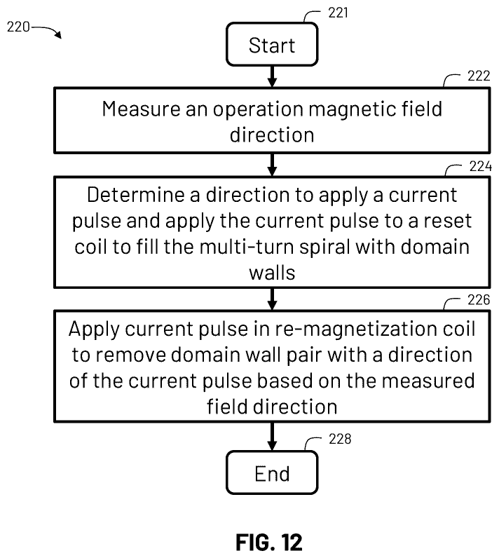

FIG. 12 shows another example method 220 for initializing a multi-turn spiral 100 in accordance with aspects of this disclosure. The method 220 begins at block 221.

At block 222, the multi-turn sensor system measures an operation magnetic field direction. For example, the operation magnetic field may be generated by a magnet such as the magnetic target 21 of FIG. 2. In some embodiments, the multi-turn sensor system can include a single turn sensor configured to measure the direction or angle of the operation magnetic field. The single turn sensor can include a quadrant detector combined with anisotropic magnetoresistance (AMR) sensor.

At block 224, the multi-turn sensor system determines in which direction to apply a current pulse to a reset coil (such as the magnetic reset 27 of FIG. 2) or a reset wire (such as the reset wires 160 of FIG. 13) to fill the multi-turn spiral 100 with domain walls. The multi-turn sensor system applies the current pulse to the rest coil or rest wire based on the determined direction of the external magnetic field from block 222. The magnitude of the current pulse is selected to generate a magnetic field having a sufficient strength to fill the multi-turn spiral 100 with domain walls.

At block 226, the multi-turn sensor system applies a current pulse to the re-magnetization coil 120 to remove at least one pair of domain walls in the multi-turn spiral 100. As in block 224, the multi-turn sensor system can determine in which direction to apply the current pulse to the re-magnetization coil 120 based on the determined direction of the external magnetic field from block 222. The method 220 ends at block 228.

Advantageously, by measuring the external magnetic field direction at block 222, the magnitudes of the current pulses applied to both the reset coil and the re-magnetization coil 120 can be reduced. That is, the multi-turn sensor system can apply the current pulses in a direction that constructively combines with the external magnetic field direction. In contrast, if the direction of the external magnetic field is unknown, the magnitude of the current pulses should generate a magnetic field sufficient to overcome the external magnetic field in that case that the external magnetic field is opposite to the generated magnetic field in order to either fill the multi-turn spiral 100 with domain walls or annihilate the pair of domain walls.

In either or both of the methods 200 or 220, rather than applying a magnetic field to the multi-turn spiral 100 with respect to a magnetic target to fill the multi-turn spiral 100 with domain walls, the sensor can fill the multi-turn spiral 100 at block 202 and/or 224 by mechanically rotating the applied magnetic field (e.g., the magnetic target 21 of FIG. 2), such that domain walls from the domain wall generator 106 propagate around the multi-turn spiral 100 until the multi-turn spiral 100 is filled with domain walls. The mechanical rotation of the applied magnetic field can be in the CW or CCW direction depending on the location of the domain wall generator 106 and the direction of the spiraling of the multi-turn spiral 100.

In some embodiments, the location of the gap in the domain walls (e.g., where the annihilated domain walls would have been located) can be moved by combining rotating the magnetic field with applied current pulses in a re-magnetization coil to provide a custom domain wall configuration pattern in the spiral after the initialization of the method 200 and/or the method 220 is completed. In some embodiments, one or more additional domain wall pairs can be annihilated to form a plurality of gaps in the domain walls in providing a custom domain wall configuration pattern. For example, the additional domain wall pairs can be annihilated after moving the additional domain wall pairs within the portion of the multi-turn spiral 100 corresponding to the re-magnetization coil 120. In some embodiments, the multi-turn spiral 100 can include a plurality of re-magnetization coils 120 positioned at different portions of the multi-turn spiral 100 and each of the re-magnetization coils 120 can be configured to annihilate one or more pairs of domain walls.

In some embodiments, the sensor can also use a measurement from a read out circuit (such as the read out circuit 28 of FIG. 2), as part of the initialization process (e.g., the method 200 and/or 220). The read out circuit can generate a resistance readout which can be used to measure the magnetization state of each of the spirals 102 and 104 of the multi-turn spiral 100. This output from the read out circuit can be used in a number of ways for the initialization process.

For example, the multi-turn sensor system can measure the magnetization state of each of the spirals 102 and 104 before and after re-magnetization of the portion 114 of the multi-turn spiral 100 (e.g., blocks 204 and 226). The multi-turn sensor system can verify that the multi-turn spiral 100 has been filled with domain walls prior to re-magnetization and verify that the pair of domain walls has been annihilated after re-magnetization.

In some embodiments, in response to detecting that the re-magnetization process was unsuccessful, the multi-turn sensor system can repeat the re-magnetization process (e.g., repeat block 204 or 226) or apply a current pulse to the re-magnetization coil 120 with a larger magnitude current.

In some embodiments, in response to detecting that the re-magnetization process was unsuccessful, the multi-turn sensor system can report the unsuccessful re-magnetization as part of the self-diagnostics of the multi-turn sensor system.

In some embodiments, the multi-turn sensor system can determine the locations of a pair of domain walls to be annihilated based on the measures magnetization state of the spiral. The multi-turn sensor system can then energize only selected portions of the re-magnetization coil 120 in which the pair domain walls to be annihilated are located.

In some embodiments, the multi-turn sensor system can energize only selected portions of the re-magnetization coil 120 based on the determined locations of the pair of domain walls, allowing the external magnetic field to move the domain walls when the direction of the external magnetic field moves the domain wall(s) in the desired direction(s) for annihilation.

In some embodiments, the multi-turn sensor system can energize selected portions of the re-magnetization coil 120 with a larger magnitude current based on the determined locations of the pair of domain walls, for example, when moving the domain wall(s) in a direction opposing the external magnetic field. This can ensure that the magnetic field applied by the re-magnetization coil 120 is sufficient to overcome the external magnetic field while also moving the domain wall(s) in the desired direction(s) for annihilation.

In some embodiments, a multi-turn sensor including the multi-turn spiral described herein can be implemented using GMR technology. GMR multiturn sensors may be combined with magnetic field angle sensor(s) and/or sensor(s) configured to measure magnetic field amplitude. These sensors may be fabricated on the same die as a GMR multi-turn sensor, on a co-packaged die, or at a system level on the same printed circuit board (PCB). These sensors can be based on AMR, GMR, TMR, and/or Hall effect technology. The multi-turn sensor can use the outputs from these sensors when re-magnetizing the multi-turn spiral segments in a similar way to how the output of the read out circuit is used as described above. For example, the re-magnetization current can be applied to a selected number of segments of the re-magnetization coil 120. In other segments of the re-magnetization coil 120, the domain walls will move due to external magnetic field. In other cases, the re-magnetization current amplitude in each segment of the re-magnetization coil 120 can be adjusted depending on strength and direction of measured external magnetic field.

FIG. 13 illustrates another embodiment of the multi-turn spiral 100 including a magnetization component which can be used to fill the multi-turn spiral 100 with domain walls in accordance with aspects of this disclosure. In the embodiment of FIG. 13, the magnetization component comprises a pair of reset wires 160 arranged over both the first spiral 102 and the second spiral 104 of the multi-turn spiral 100. In other embodiments, the magnetization component can comprise one or more domain wall generators configured to provide domain walls to one or both of the first spiral 102 and the second spiral 104. The reset wires 160 can be monolithically integrated with the multi-turn spiral 100 in combination with the re-magnetization coil 120. The reset wires 160 can fill the multi-turn spiral 100 with domain walls. Although FIG. 13 illustrates an embodiment in which the reset wires 160 are embodied as wires, in other embodiments, the reset wires 160 can be replaced with reset coils configured to fill the multi-turn spiral 100 with domain walls.

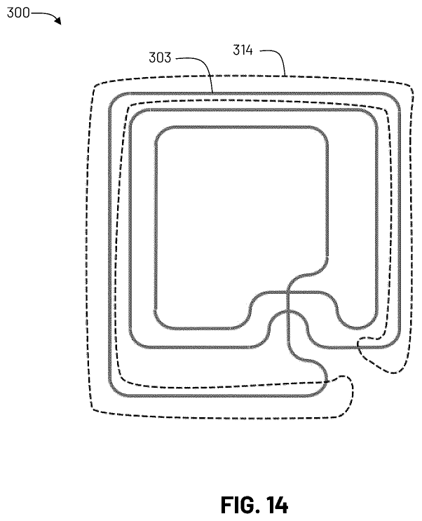

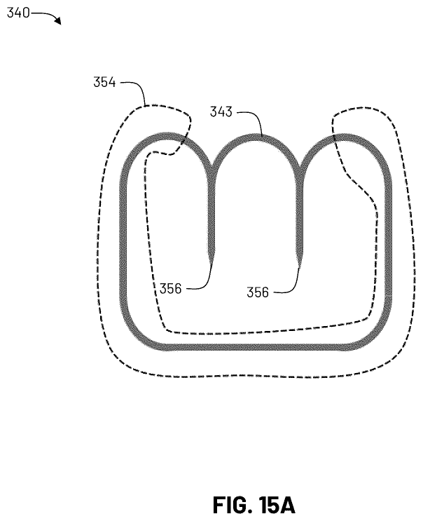

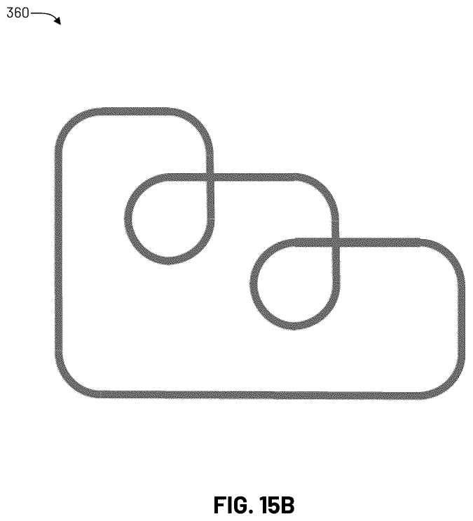

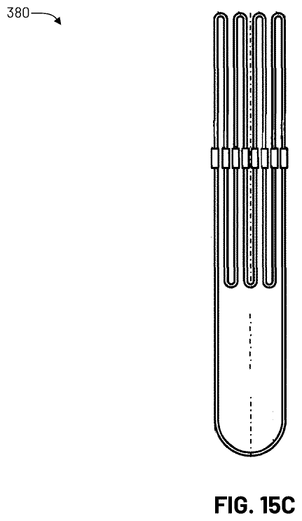

Although certain embodiments include open loop spirals, any suitable principles and advantages disclosed herein can be applied to closed loop spirals for multi-turn magnetic sensing. FIG. 14 illustrates another embodiment of a multi-turn spiral 300 in accordance with aspects of this disclosure. FIG. 15A illustrates an embodiment of a multi-turn counter loop 340 in accordance with aspects of this disclosure. FIG. 15B illustrates another embodiment of a multi-turn counter loop 360 in accordance with aspects of this disclosure. FIG. 15C illustrates yet another embodiment of a multi-turn counter loop 380 in accordance with aspects of this disclosure.

With reference to FIG. 14, the multi-turn spiral 300 can include a nanowire 303 formed in a closed loop spiral. In some embodiments, the closed loop multi-turn spiral 300 can include a syphon structure or a bridge to allow domain walls to continuously propagate around the multi-turn spiral 300. A re-magnetization component (not illustrated in FIG. 14) can be positioned such that the re-magnetization component can magnetize the portion 314 of the multi-turn spiral 300 to annihilate a pair of domain walls. The re-magnetization component can be a re-magnetization coil, for example. The re-magnetization component can be embodied in accordance with any suitable principles and advantages described herein.

In FIG. 15A, the multi-turn counter loop 340 can include a nanowire 343 formed in a closed loop having multiple stopping structures 356, which may be referred to as inwardly oriented tapered protuberances. The multiple stopping structures 356 can be implemented in accordance with any suitable principles and advantages disclosed in U.S. Patent Pub. No. 2010/0301842, the disclosure of which is hereby incorporated by reference in its entirety and for all purposes. In some embodiments, the closed loop multi-turn counter loop 340 can include a divider structure to allow domain walls to continuously propagate around the multi-turn counter loop 340. A re-magnetization component (not illustrated) can be positioned such that the re-magnetization component can magnetize the portion 354 of the multi-turn counter loop 340 to annihilate a pair of domain walls. The re-magnetization component can be a re-magnetization wire or a re-magnetization coil, for example. The re-magnetization component can be embodied in accordance with any suitable principles and advantages described herein.

With reference to FIGS. 15B and 15C, the multi-turn counter loops 360, 380 can have other structures configured to detect a turn count of an operation magnetic field. A re-magnetization component (not illustrated) can be positioned such that the re-magnetization component can magnetize a portion of the multi-turn counter loops 360, 380 to annihilate a pair of domain walls. The re-magnetization component can be a re-magnetization wire or a re-magnetization coil, for example. The re-magnetization component can be embodied in accordance with any suitable principles and advantages described herein.

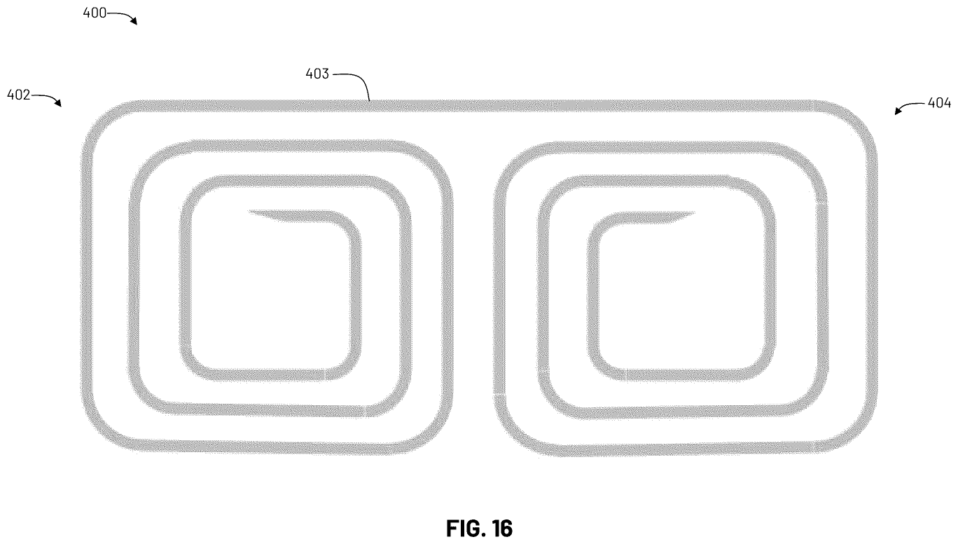

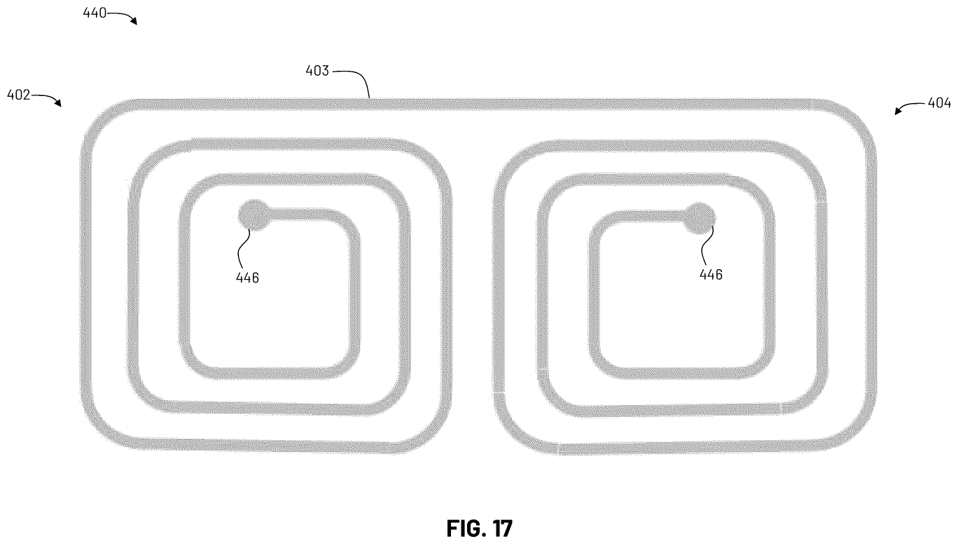

Although certain embodiments include one domain wall generation connected to an end of a multi-turn spiral, any suitable principles and advantages disclosed herein can be applied to multi-turn spirals that are not connected to a domain wall generator or that are connected to more than one domain wall generator. FIG. 16 illustrates still yet another embodiment of a multi-turn spiral 400 in accordance with aspects of this disclosure. FIG. 17 illustrates another embodiment of a multi-turn spiral 440 in accordance with aspects of this disclosure.

As shown in FIG. 16, the multi-turn spiral 400 can include a first spiral 402 and a second spiral 404 coupled together such that domain walls can propagate between the first and second spirals 402 and 404. The first spiral 402 and second spiral 404 can be formed from a nanowire 403. The multi-turn spiral 400 of FIG. 16 does not include a domain wall generator.

In case of an open loop multi-turn spiral 400 without domain wall generators as shown in FIG. 16, it can be desirable to ensure that there is at least one domain wall left adjacent to the domain wall gap generated by the re-magnetization. For example, over-turning the multi-turn spiral 400 in either the CW direction or CCW direction could delete one of the domain walls adjacent to the domain wall gap, resulting in the turn count information being ambiguous. Accordingly, avoiding such over-turning can be advantageous.

With reference to FIG. 17, the multi-turn spiral 440 can include a first spiral 402 and a second spiral 404 coupled together such that domain walls can propagate between the first and second spirals 402 and 404. The first spiral 402 and second spiral 404 can be formed from a nanowire 403. The multi-turn spiral 440 of FIG. 17 also includes a pair of domain wall generators 446 at both ends of the multi-turn spiral 440.

In case of an open loop spiral with two domain wall generators as illustrated in the embodiment of FIG. 17, it can be desirable to ensure that the domain wall gap does not enter either of the domain wall generators 446. An over-turning in the CW or CCW direction could fill the domain wall gap with new domain walls and the turn count information would be ambiguous. Accordingly, avoiding such over-turning can be advantageous.

In case of an open loop spiral with one domain wall generator 106, for example as shown in FIG. 1, it can be desirable to ensure that on the domain wall generator 106 side, the domain wall gap does not enter the domain wall generator 106. If the domain wall gap were to enter the domain wall generator 106, the gap could be filled with new domain walls and the turn count information would be ambiguous. On the end without domain wall generator 106, it would be allowable to turn until the domain wall gap disappears on this end but not any further. Not pushing the domain wall adjacent to the gap on the domain wall generator side out of the multi-turn spiral 100 is desirable. An overturning would result in a false turn count information. Accordingly, avoiding such over-turning can be advantageous.

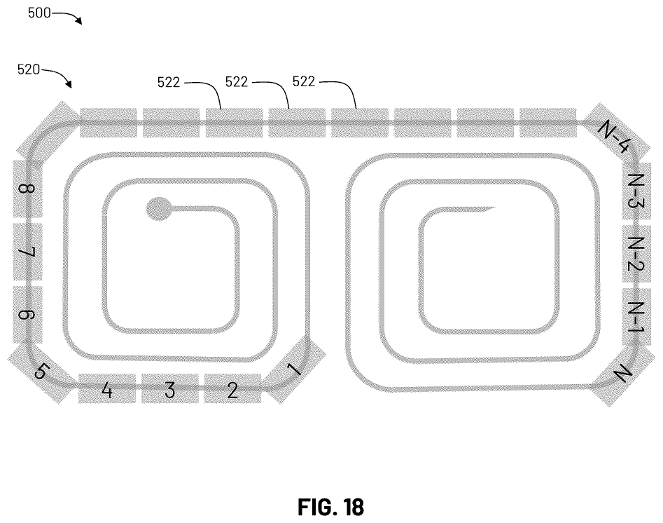

In certain embodiments, a re-magnetization component can be split into sections that can be energized for annihilating domain walls. The sections can be connected in parallel with each other. FIG. 18 illustrates another embodiment of the multi-turn spiral 500 including a one or more wires configured to annihilate at least two domain walls of the multi-turn spiral 500 in accordance with aspects of this disclosure. In contrast to the embodiments of FIGS. 5 and 10, the one or more wires of FIG. 18 include a re-magnetization coil 520 having a plurality of sections 522, a selection of which are numbered in FIG. 18. The sections 522 of the re-magnetization coil 520 can be powered in sequence to move the pair of domain walls towards each other and annihilate when they meet. For example, the sequence can include applying a current pulse to sections 1 and N−1, sections 2 and N−2, sections 3 and N−3, etc. In some embodiments, the current pulses can be applied such that adjacent sections 522 are energized with at least some overlap. For example, sections 2 and N−2 may be energized before the sections 1 and N are de-energized.

In embodiments where the multi-turn sensor system has measured the direction of the external magnetic field, the multi-turn sensor system may not energize certain sections of the plurality of sections 522 of the re-magnetization coil 520 as domain walls can propagate due to applied external magnetic field. This can reduce the power used to annihilate the pair of domain walls.

By using a re-magnetization coil 520 having a plurality of sections 522, the total amount of current applied to the plurality of sections 522 may be less than a current pulse applied to a single re-magnetization coil (such as the re-magnetization coil 120 of FIG. 5 or FIG. 10). For example, when using a single coil as the re-magnetization coil, the coil resistance may be relatively high. Thus, a relatively higher voltage may be used for the current pulse to overcome the coil resistance. In some implementations, the magnitude of the current pulse may be difficult to generate using the supply voltage available on the muti-turn sensor system. Thus, using a re-magnetization coil 520 having a plurality of sections 522 may be more practical in embodiments having limited supply voltages.

In some embodiments, the plurality of sections 522 can be electrically connected in parallel, thereby reducing the total resistance and increasing the total current to re-magnetize the desired spiral area.

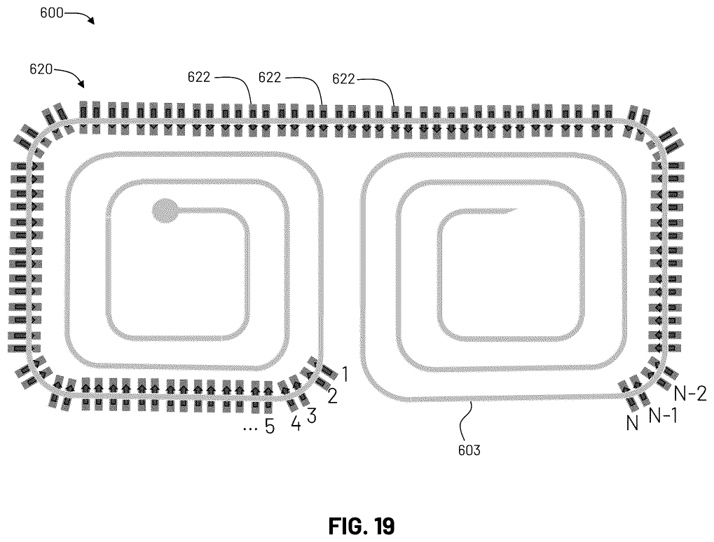

Although certain embodiments include re-magnetization coils, any other suitable re-magnetization component can alternatively or additionally be used to annihilate domain walls. FIG. 19 illustrates yet another embodiment of the multi-turn spiral 600 including one or more wires forming a re-magnetization component 620 which can be used to re-magnetize a portion of the multi-turn spiral 600 in accordance with aspects of this disclosure. In contrast to the embodiment of FIG. 18, the re-magnetization component 620 includes a plurality of metallic sections 622, a selection of which are numbered in FIG. 19. As illustrated, the plurality of metallic sections 622 can be in a single layer. The plurality of metallic sections 622 can be located adjacent to a nanowire 603 forming the multi-turn spiral 600, for example above or below the nanowire 603. Advantageously, manufacturing a re-magnetization component 620 having plurality of metallic sections 622 in a single layer may have a simpler process integration than embodiments employing a spiral coil that winds around the nanowire 603. A spiral coil that winds around the nanowire 603 may be more efficient at generating a magnetic field compared to the plurality of metallic sections 622 on one side of the nanowire 603 in certain applications.

In some embodiments, the plurality of metallic sections 622 can be spaced apart from the nanowire 603 by a predetermined distance. For example, the predetermined distance may be selected to ensure that the plurality of metallic sections 622 are close enough to the nanowire 603 to enable generating a magnetic field with a sufficient strength at the nanowire 603 while also being spaced far enough from the nanowire 603 to ensure that the plurality of metallic sections 622 are not shorted to the nanowire 603, for example, as a result of manufacturing variation.

In some embodiments, the plurality of metallic sections 622 may be connected in parallel to each other. In other embodiments, the plurality of metallic sections 622 can be energized in sequential order, similar to the sequential order described in connection with FIG. 18.

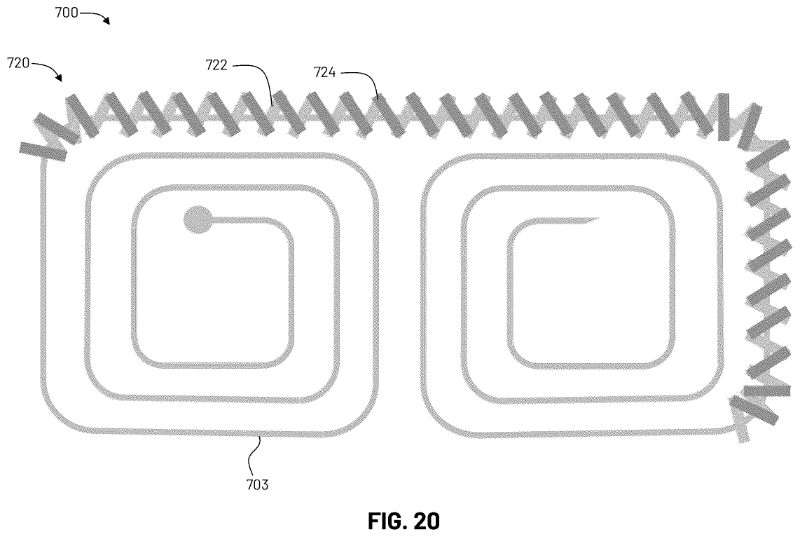

FIG. 20 illustrates still yet another embodiment of the multi-turn spiral 700 including a re-magnetization component which can be used to re-magnetize a portion of the multi-turn spiral 700 in accordance with aspects of this disclosure. In contrast to the embodiments of FIGS. 5 and 10, the re-magnetization component includes a re-magnetization coil 720 formed on one side (e.g., above or below) the nanowire 703. The re-magnetization coil 720 includes a plurality of first wires 722 and a plurality of second wires 724 located above the first wires 722. In the embodiment of FIG. 20 where the re-magnetization coil 720 is located above the nanowire 703, the first wires 722 can produce a magnetic field for annihilating a pair of domain walls. The second wires 724 may not significantly affect the magnetic field produced by the first wires 722. For example, the second wires 724 may generate a coulter magnetic field on nanowire 703 which has a lower magnitude due to a larger distance from the nanowire 703.

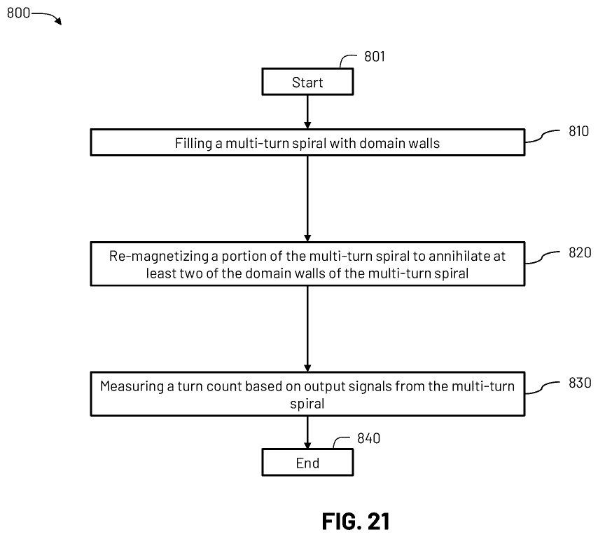

FIG. 21 shows an example method 800 for initializing a multi-turn magnetic sensing system in accordance with aspects of this disclosure. The method 800 begins at block 801.

At block 810, the method 800 involves filling a multi-turn spiral with domain walls. For example, the multi-turn magnetic sensing system can include a magnetization component configured to fill the multi-turn spiral with domain walls.

At block 820, the method 800 involves re-magnetizing a portion of the multi-turn spiral to annihilate at least two of the domain walls of the multi-turn spiral. For example, the multi-turn magnetic sensing system can include a re-magnetization component configured to generate a magnetic field over a portion of the multi-turn spiral to annihilate the domain walls within the portion of the multi-turn spiral. The re-magnetization component can be implemented in accordance with any suitable principles and advantages disclosed herein.

At block 830, the method 800 involves measuring a turn count based on output signals from the multi-turn spiral. For example, the multi-turn magnetic sensing system can include a decoder configured to determine the turn count in based on a location of a domain wall gap formed by the annihilation of the at least two of the domain walls. The method 800 ends at block 840.

### Mid-Position Reset of Multi-Turn Magnetic Sensors

Aspects of this disclosure relate to resetting multi-turn magnetic sensors to a reset state that corresponds to a turn count that is between a first value and a second value of a turn count range corresponding to states of two multi-turn magnetic sensors. The first value can be a minimum value of a turn count range, and the second value can be a maximum value of the turn count range. Accordingly, a multi-turn magnetic sensing system can track CW rotation of a magnetic field from the reset state and track CCW rotation of the magnetic field from the reset state.

In some embodiments, a multi-turn magnetic sensing system can include two multi-turn magnetic sensors, one CW multi-turn magnetic sensor and one CCW multi-turn magnetic sensor. Domain walls can propagate in opposite directions in the CW multi-turn sensor and the CCW multi-turn magnetic sensor. Both the CW multi-turn magnetic sensor and the CCW multi-turn magnetic sensor can be reset in an initialization phase to a reset state. The reset state can correspond to both of the multi-turn magnetic sensors being filled with domain walls.

From the reset state, the multi-turn magnetic sensing system can count a cumulative number of turns in the CW direction and/or in the CCW direction. If the magnetic field rotates in the CW direction from the reset state, then the CCW sensor counts down from N to 0, where N is the maximum number of turns. At the same time, the CW sensor can remain at its maximum N turn state. Similarly, if the magnetic field rotates in the CCW direction from the reset state, then the CW sensor can count down from N to 0, where N is the maximum number of turns. At the same time, the CCW sensor can remain in its maximum N turn state.

FIG. 22A is a schematic diagram of two multi-turn sensors of a multi-turn magnetic sensing system according to an embodiment. FIG. 22B is a table summarizing state and turn count for the multi-turn magnetic sensing system of FIG. 22A as a magnetic field rotates. FIG. 22A illustrates a multi-turn magnetic sensing system 10 with a CW sensor and a CCW sensor with magnetic reset capability capable of measuring+/−N turns of a rotating magnetic field with mid-range magnetic reset.

Referring to FIG. 22A, the multi-turn magnetic sensing system 10 includes a first magnetic spiral 12 and a second magnetic spiral 14. The magnetic spirals 12 and 14 each implement a respective multi-turn magnetic sensor. The magnetic spirals 12 and 14 each include a plurality of magnetoresistive elements 15 that are arranged in series with each other. Each side of the magnetic spiral 12, 14 between consecutive corners of the magnetic spiral 12, 14 includes a magnetoresistive element 15. The magnetic spirals 12 and 14 each include 6 turns and 24 magnetoresistive elements 15. The magnetic spirals 12 and 14 can each include a domain wall generator 16 at an end of the spiral. In certain applications, the first magnetic spiral 12 and the second magnetic spiral 14 can be on a single die. Alternatively, the first magnetic spiral 12 and the second magnetic spiral 14 can be on different die.

The multi-turn magnetic sensing system 10 can count+/−3 turns of a magnetic field from a reset state. The reset state can correspond to a turn count that is between endpoints of the count range. For example, in the multi-turn magnetic sensing system 10, the reset state can correspond to a midpoint of the count range. For a +/−3 count range, the first magnetic spiral 12 and the second magnetic spiral 14 can each have a 6-turn measurement range. For example, as illustrated in FIG. 22A, the first magnetic spiral 12 can count 6 turns of a magnetic field in the CW direction and the second magnetic spiral 14 can count 6 turns of the magnetic field in the CCW direction. In the multi-turn magnetic sensing system 10, the reset state can correspond to the midpoint of the turn count range. This can be due to the first magnetic spiral 12 and the second magnetic spiral 14 having the same number of turns.

In this disclosure, the CW turns are indicated as positive turns and CCW turns are indicated as negative turns. The opposite convention where CCW turns are positive turns and CW turns are negative turns can be used to describe the same functionality.

Operation of the multi-turn magnetic sensing system 10 will be discussed with reference to FIG. 22B. The first magnetic spiral 12 and the second magnetic spiral 14 can be reset. This can fill each of the magnetic spirals 12, 14 with domain walls. In the reset state, the first magnetic spiral 12 and the second magnetic spiral 14 can both be at a maximum state, which is 6 in this example. The turn count of the multi-turn magnetic sensing system 10 can represent the cumulative number of turns from the reset state. Accordingly, for the reset state, the turn count is 0. This state can be system state A of the multi-turn magnetic sensing system 10.

As the magnetic field rotates CW for 3 full turns, the turn count of the second magnetic spiral 14 can decrease and the state of the first magnetic spiral 12 can remain the same. The turn count of the multi-turn magnetic sensing system 10 can increase by 1 for each full CW rotation of the magnetic field. The states of the multi-turn magnetic sensing system 10 after 1 full CW rotation from the reset state, 2 full CW rotations from the reset state, and 3 full CW rotations from the reset state are B, C, and D, respectively, in FIG. 22B.

As the magnetic field rotates CW for 3 full turns, the turn count of the second magnetic spiral 14 can decrease and the turn count of the first magnetic spiral 12 can remain the same. The turn count of the multi-turn magnetic sensing system 10 can increase by 1 for each full CW rotation of the magnetic field. The states of the multi-turn magnetic sensing system 10 after 1 full CW rotation from the reset state, 2 full CW rotations from the reset state, and 3 full CW rotations from the reset state are B, C, and D, respectively, in FIG. 22B.

From system state D, the magnetic field can rotate 3 full CCW turns. The turn count of the first magnetic spiral 12 can decrease and the turn count of the second magnetic spiral 14 can increase. The turn count of the multi-turn magnetic sensing system 10 can decrease by 1 for each full CCW rotation of the magnetic field. The states of the multi-turn magnetic sensing system 10 after these full CCW magnetic field rotations from system state D are E, F, and G, respectively. At state G of the system, the system turn count is back to 0 after 3 CW and 3 CCW rotations from the reset state.

The magnetic field can rotate CW for 3 more full turns, where first magnetic spiral 12 can decrease and the turn count of the second magnetic spiral 14 can increase.

After a magnetic field cumulatively rotates 3 turns in each direction from the reset state, the multi-turn magnetic sensing system 10 can operate in equilibrium. The first system state K and subsequent states of FIG. 22B correspond to the multi-turn magnetic sensing system 10 operating in equilibrium. Once equilibrium is reached, the multi-turn magnetic sensing system 10 operates in one of 7 system states for full turns of the magnetic field, where these system states correspond to full turn counts of −3 to +3. These 7 system states are states J, K, L, M, N, O, and P in FIG. 22B. A preconditioning circuit and a decoder can be used to decode valid pre-equilibrium states to turn counts. In FIG. 22B, states A, B, C, D, E, F, G, H, and I are valid pre-equilibrium states from which turn count of the system can be decoded.

As indicated by FIG. 22B, the multi-turn magnetic sensing system 10 can have more than one system state that corresponds to the same turn count. For instance, there can be a pre-equilibrium state and an equilibrium state that both correspond to the same turn count. As one example, system states H and L both correspond to a turn count of −1. As another example, system states B, F, and N each correspond to a turn count of 1. This example illustrates that more than one pre-equilibrium state can correspond to the same turn count as one equilibrium state.

In FIG. 22B, 16 system states (i.e., states A to P) corresponding to full turns from the reset state are shown. Other valid states are possible for the multi-turn magnetic sensing system 10. The other valid states can be pre-equilibrium states. As one example of another valid state, 1 CCW rotation from the reset state is another possible valid state.

Operation of the multi-turn magnetic sensing system 10 is discussed above with reference to full rotations of a magnetic field. The multi-turn magnetic sensing system 10 can track turns with a different resolution in accordance with any suitable principles and advantages disclosed herein. For example, a decoder can determine a turn count from output signals associated with the first magnetic spiral 12 and/or the second magnetic spiral 14 with a half turn resolution or quarter turn resolution. With a half turn resolution, there are can an intermediate state between any two consecutive states associated with full turns in which the intermediate state can correspond to a half turn between the two consecutive full turn states. With a quarter turn resolution, there are can 3 intermediate states between any two consecutive states associated with full turns where the intermediate states can correspond to a quarter turn, a half turn, and three quarters of a turn.

Any suitable principles and advantages disclosed with reference to FIGS. 22A and/or 22B can be applied to a multi-turn magnetic sensing system that can count+/−N turns, where a CW sensor and a CCW sensor each individually have a measurement range of 2N turns. With rollover counting and indexing, any suitable principles and advantages disclosed with reference to FIG. 22A and/or 22B can be applied to a multi-turn magnetic sensing system with rollover counting where the turn count can have a value with a magnitude that is greater than the number of turns of an individual multi-turn magnetic sensor.

Although the magnetic spirals 12 and 14 are configured to count the same number of turns as each other, any suitable principles and advantages disclosed with reference to FIGS. 22A and/or 22B can be applied to two magnetic spirals that can count a different number of turns. For two magnetic spirals that can count a different number of turns, the reset state may not be in the exact midpoint of the system turn count range.

### APPLICATIONS, TERMINOLOGY, AND CONCLUSION

Multi-turn magnetic sensing systems disclosed herein can be implemented in any suitable application that can benefit from counting turns of a rotating magnetic field. Example applications include, but are not limited to, electronic power steering (EPS) applications such as EPS steer-by-wire actuator applications, parking lock actuators, seat belt retractors, transmission actuators, other vehicular applications, robot and/or robot applications such as arm joint position tracking, rotary to linear actuator applications, wire drawn encoder applications, other industrial automation applications, and the like.

In the embodiments described above, sensors, circuits, systems, and methods for multi-turn magnetic sensing are described in connection with particular embodiments. It will be understood, however, that the principles and advantages of the embodiments can be used for any other suitable sensors, circuits, systems, and methods with a multi-turn magnetic sensing.

Unless the context clearly requires otherwise, throughout the description and the claims, the words “comprise,” “comprising,” “include,” “including,” and the like are to be construed in an inclusive sense, as opposed to an exclusive or exhaustive sense; that is to say, in the sense of “including, but not limited to.” The words “coupled” or connected”, as generally used herein, refer to two or more elements that may be either directly connected, or connected by way of one or more intermediate elements. Thus, although the various schematics shown in the figures depict example arrangements of elements and components, additional intervening elements, devices, features, or components may be present in an actual embodiment (assuming that the functionality of the depicted circuits is not adversely affected). Additionally, the words “herein,” “above,” “below,” and words of similar import, when used in this application, shall refer to this application as a whole and not to any particular portions of this application. Where the context permits, words in the Detailed Description using the singular or plural number may also include the plural or singular number, respectively. The words “or” in reference to a list of two or more items, is intended to cover all of the following interpretations of the word: any of the items in the list, all of the items in the list, and any combination of the items in the list. All numerical values provided herein are intended to include similar values within a measurement error.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states.

The teachings of the embodiments provided herein can be applied to other systems, not necessarily the systems described above. The elements and acts of the various embodiments described above can be combined to provide further embodiments. The acts of the methods discussed herein can be performed in any order as appropriate. Moreover, the acts of the methods discussed herein can be performed serially or in parallel, as appropriate.

While certain embodiments of the inventions have been described, these embodiments have been presented by way of example only, and are not intended to limit the scope of the disclosure. Indeed, the novel circuits, methods, and systems described herein may be embodied in a variety of other forms. Furthermore, various omissions, substitutions and changes in the form of the circuits, methods, apparatus and systems described herein may be made without departing from the spirit of the disclosure. For example, while the disclosed embodiments are presented in given arrangements, alternative embodiments may perform similar functionalities with different components and/or circuit topologies, and some elements may be deleted, moved, added, subdivided, combined, and/or modified. Each of these elements may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure. Accordingly, the scope of the present inventions is defined by reference to the claims.

Although the claims presented here are in single dependency format for filing at the USPTO, it is to be understood that any claim may depend on any preceding claim of the same type except when that is clearly not technically feasible.

What is claimed is:

1. A multi-turn magnetic sensing system comprising:
a multi-turn loop through which domain walls propagate in response to rotation of a magnetic field;
a magnetization component configured to provide the domain walls to the multi-turn loop; and
one or more wires configured to annihilate at least two of the domain walls of the multi-turn loop.

2. The multi-turn magnetic sensing system of claim 1, wherein the magnetization component comprises a reset wire configured to fill the multi-turn loop with domain walls.

3. The multi-turn magnetic sensing system of claim 1, further comprising a decoder configured to output a turn count that is based on output signals from the multi-turn loop, wherein the decoder is configured to determine the turn count in based on a location of a domain wall gap formed by the annihilation of the at least two of the domain walls.

4. The multi-turn magnetic sensing system of claim 1, wherein the one or more wires comprise a re-magnetization coil that wraps around a portion of the multi-turn loop.

5. The multi-turn magnetic sensing system of claim 1, wherein the one or more wires comprise a re-magnetization component positioned on one side of a portion of the multi-turn loop.

6. The multi-turn magnetic sensing system of claim 1, wherein the multi-turn loop comprises a multi-turn spiral, and wherein the one or more wires comprise a re-magnetization component that covers at least three quarters of a turn of the multi-turn spiral.

7. The multi-turn magnetic sensing system of claim 1, further comprising:
a read out circuit configured to measure a direction of an external magnetic field; and
a controller configured to apply a current pulse to the one or more wires with a direction of the current pulse based on the measured external magnetic field.

8. The multi-turn magnetic sensing system of claim 7, wherein:
the read out circuit is further configured to measure a magnetization state of the multi-turn loop, and
the controller is configured to verify that the at least two of the domain walls were annihilated based on the measured magnetization state of the multi-turn loop.

9. The multi-turn magnetic sensing system of claim 1, wherein the multi-turn loop comprises a multi-turn spiral, and wherein the magnetization component comprises:
a domain wall generator configured to generate domain walls at one end of the multi-turn spiral; and
a magnetic target configured to generate an external magnetic field,
wherein the providing domain walls to the multi-turn spiral comprises turning the magnetic target with respect to the multi-turn spiral such that the domain walls generated by the domain wall generator propagate around the multi-turn spiral.

10. The multi-turn magnetic sensing system of claim 1, wherein the magnetization component comprises:
one or more reset wires configured to generate a magnetic field having a strength sufficient to fill the multi-turn loop with the domain walls.

11. The multi-turn magnetic sensing system of claim 1, wherein the multi-turn loop comprises a multi-turn spiral including a first spiral and a second spiral, the first spiral and the second spiral coupled together such that domain walls can propagate between the first and second spirals.

12. The multi-turn magnetic sensing system of claim 1, wherein the one or more wires comprise a re-magnetization component including a plurality of sections, and the multi-turn magnetic sensing system further comprises a controller configured to apply current pulses to the sections of the re-magnetization component in sequence.

13. A method of initializing a multi-turn magnetic sensing system, the method comprising:
providing domain walls to a multi-turn loop; and
applying a magnetic field to a portion of the multi-turn loop to annihilate at least two of the domain walls of the multi-turn loop,
wherein after the applying the multi-turn loop is configured to change state in response to rotation of a magnetic field.

14. The method of claim 13, further comprising determining a turn count based on output signals from the multi-turn loop.

15. The method of claim 14, wherein the determining is based on a location of a domain wall gap formed by the annihilation of the at least two of the domain walls.

16. The method of claim 13, wherein the applying is performed using a coil that wraps around a portion of the multi-turn loop.

17. The method of claim 13, further comprising measuring a direction of an external magnetic field, wherein the applying comprises applying a current pulse to a re-magnetization component, and wherein a direction of the current pulse is based on the measured external magnetic field.

18. The method of claim 13, further comprising:
measuring a magnetization state of the multi-turn loop; and
verifying that the at least two of the domain walls were annihilated based on the measured magnetization state of the multi-turn loop.

19. The method of claim 13, wherein the providing the domain walls to the multi-turn loop is performed using one or more reset wires that generate a magnetic field having a strength sufficient to fill the multi-turn loop with the domain walls.

20. A multi-turn magnetic sensing system comprising:
a multi-turn loop through which domain walls propagate in response to rotation of a magnetic field;
means for annihilating at least two of the domain walls of the multi-turn loop; and
a decoder configured to output a turn count that is based on output signals from the multi-turn loop.
